(19) United States
(12) Patent Application Publication
(10) Pub. No.: US 2025/0226274 A1
(43) Pub. Date: Jul. 10, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Younjeong CHOE, Suwon-si (KR); Dahee KIM, Suwon-si (KR); Taehoon LEE, Suwon-si (KR); Gyujin CHOI, Suwon-si (KR)

(73) Assignee: Samsung Electronics Co., Ltd., Suwon-si (KR)

(21) Appl. No.: 18/753,110

(22) Filed: Jun. 25, 2024

(30) Foreign Application Priority Data
Jan. 8, 2024 (KR) 10-2024-0002787
Feb. 5, 2024 (KR) 10-2024-0017332

(51) Int. Cl. H01L 23/18; H01L 23/00; H01L 23/31; H01L 23/498; H01L 23/538

(52) U.S. Cl. CPC H01L 23/18; H01L 23/3107; H01L 23/5383; H01L 24/24; H01L 23/49816; H01L 24/08; H01L 2224/08225; H01L 2224/24

(57) ABSTRACT

A semiconductor package includes a first redistribution structure including a gap fill layer covering at least a portion of interconnection patterns, a first insulating layer covering the gap fill layer, a first redistribution layer below the first insulating layer, and a first redistribution via electrically connecting the first redistribution layer to the interconnection patterns, wherein the interconnection patterns include a first pattern layer adjacent to a first surface and embedded in the insulating material layer, and a second pattern layer adjacent to a second surface and protruding on the insulating material layer, and the gap fill layer fills at least a portion of a first region between a side surface of the first pattern layer and the insulating material layer, and at least a portion of a second region between a lower surface of the first pattern layer and the first insulating layer.

### CROSS-REFERENCE TO RELATED APPLICATION(S)

This application claims benefit of priority to Korean Patent Application No. 10-2024-0002787 filed on Jan. 8, 2024, and Korean Patent Application No. 10-2024-0017332 filed on Feb. 5, 2024 in the Korean Intellectual Property Office, the disclosures of which are incorporated herein by reference in their entirety.

### BACKGROUND

The present inventive concepts relate to a semiconductor package and a method of manufacturing the same.

Semiconductor packages may include heterogeneous materials such as a semiconductor chip, a redistribution structure, an encapsulant, and/or the like. However, voids, cracks, and/or the like that occur on and/or at interfaces between the heterogeneous materials which may cause reduced reliability, and therefore solutions are being explored.

### SUMMARY

An aspect of the present inventive concepts are to provide a semiconductor package having improved reliability and a method of manufacturing the same.

According to an aspect of the present inventive concepts, a semiconductor package includes an interconnection structure including interconnection patterns, an insulating material layer covering at least a portion of the interconnection patterns, the insulating material layer defining opposing first and second surfaces and a through-portion extending from the first surface to the second surface, and interconnection vias electrically connecting the interconnection patterns in the insulating material layer; a semiconductor chip in the through-portion, the semiconductor chip including connection pads; a molded layer covering at least a portion of the semiconductor chip and at least a portion of the interconnection structure; a first redistribution structure below the first surface of the interconnection structure and including a gap fill layer covering at least a portion of the interconnection patterns, a first insulating layer covering the gap fill layer, a first redistribution layer below the first insulating layer, and a first redistribution via electrically connecting the first redistribution layer to the connection pads and the interconnection patterns; a second redistribution structure on the second surface of the interconnection structure, the second redistribution structure including a second redistribution layer on the molded layer, and a second redistribution via electrically connecting the second redistribution layer to the interconnection patterns; and connection bumps below the first redistribution structure and electrically connected to the first redistribution layer, wherein the interconnection patterns include a first pattern layer adjacent to the first surface and embedded in the insulating material layer, and a second pattern layer adjacent to the second surface and protruding from the insulating material layer, and wherein the gap fill layer fills at least a portion of a first region between a side surface of the first pattern layer and the insulating material layer, and at least a portion of a second region between a lower surface of the first pattern layer and the first insulating layer.

According to an aspect of the present inventive concepts, a semiconductor package includes an interconnection structure including an insulating material layer defining opposing first and second surfaces and a through-portion extending from the first surface to the second surface, first pattern layers adjacent to the first surface and embedded in the insulating material layer, and second pattern layers adjacent to the second surface and protruding on the insulating material layer; a semiconductor chip in the through-portion of the interconnection structure, the semiconductor chip including connection pads on an active surface; a molded layer covering at least a portion of the semiconductor chip and at least a portion of the interconnection structure; and a redistribution structure below the first surface of the interconnection structure and the active surface of the semiconductor chip, the redistribution structure including a gap fill layer covering at least a portion of each of the first pattern layers, an insulating layer covering the gap fill layer, a redistribution layer below the insulating layer, and a redistribution via electrically connecting the redistribution layer to the connection pads and the first pattern layers, wherein at least a portion of the gap fill layer is between the insulating material layer and a side surface of at least one first pattern layer among the first pattern layers.

According to an aspect of the present inventive concepts, a method of manufacturing a semiconductor package includes attaching an interconnection structure having a through-portion to a first carrier, wherein the interconnection structure includes an insulating material layer and embedded pattern layers in the insulating material layer; disposing a semiconductor chip in the through-portion such that connection pads on an active surface face the first carrier; forming a preliminary package structure by forming a molded layer covering at least a portion of the interconnection structure and at least a portion of the semiconductor chip; transferring the preliminary package structure to a second carrier such that the connection pads and the embedded pattern layers are exposed from the second carrier; roughening an exposed surface on the embedded pattern layers; and forming a redistribution structure on the preliminary package structure, wherein forming the redistribution structure includes forming a gap fill layer covering at least a portion of each of the embedded pattern layers such that the gap fill layer fills at least a portion of a region between the embedded pattern layers and the insulating material layer.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a cross-sectional view of a semiconductor package according to at least one example embodiment, FIG. 1B is a plan view illustrating a cross-section taken along line I-I′ of FIG. 1A, and FIG. 1C is a partially enlarged view of portion ‘A’ of FIG. 1A.

FIG. 2A is a cross-sectional view of a semiconductor package according to at least one example embodiment, FIG. 2B is a plan view illustrating a cross-section taken along line II-II′ of FIG. 2A, and FIG. 2C is a partially enlarged view of portion ‘B’ of FIG. 2A.

FIG. 3A is a cross-sectional view of a semiconductor package according to at least one example embodiment, and FIG. 3B is a partial enlarged view of portion ‘C’ of FIG. 3A.

FIG. 4A is a cross-sectional view of a semiconductor package according to at least one example embodiment, and FIG. 4B is a partial enlarged view of portion ‘D’ of FIG. 4A.

FIG. 5A is a cross-sectional view of a semiconductor package according to at least one example embodiment, FIG. 5B is a partial enlarged view of portion ‘E’ of FIG. 5A, and

FIG. 5C is a view illustrating an example modification of portion ‘E’.

FIG. 6 is a cross-sectional view of a semiconductor package according to at least one example embodiment.

FIGS. 7A to 7G are views illustrating a process of manufacturing the semiconductor package illustrated in FIG. 1A.

### DETAILED DESCRIPTION

Hereinafter, preferred embodiments of the present inventive concepts will be described with reference to the accompanying drawings. Hereinafter, it can be understood that spatially relative terms, such as ‘on,’ ‘upper,’ ‘upper portion,’ ‘upper surface,’ ‘below,’ ‘lower,’ ‘lower portion,’ ‘lower surface,’ ‘side surface,’ and/or the like, may be denoted by reference numerals and refer the spatial relationship between elements illustrated in the drawings, except where otherwise indicated. Therefore, it will also be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, of “X” to “Y” provides a range including all values between X and Y, including X and Y.

Additionally, ordinal numbers such as “first,” “second,” “third,” or the like may be used as labels for specific elements, steps, operations, directions, or the like to distinguish various elements, steps, operations, directions, or the like from each other. Terms that may not be described using “first,” “second,” or the like in the specification may still be referred to as “first” or “second” in the claims. Additionally, terms referenced by a particular ordinal number (e.g., “first” in a particular claim) may be described elsewhere with a different ordinal number (e.g., “second” in the specification or another claim).

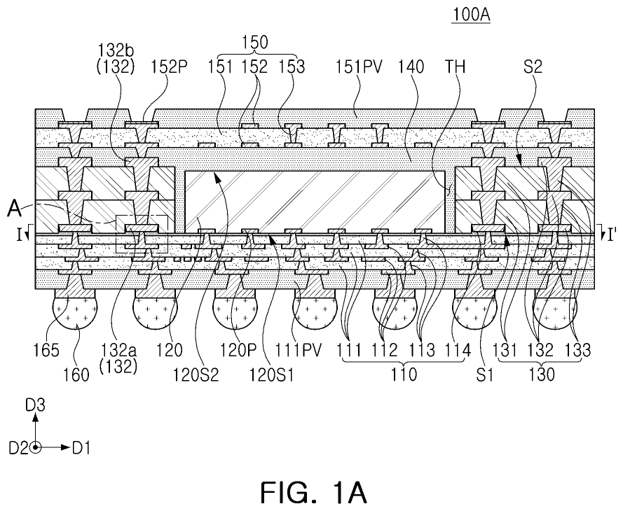

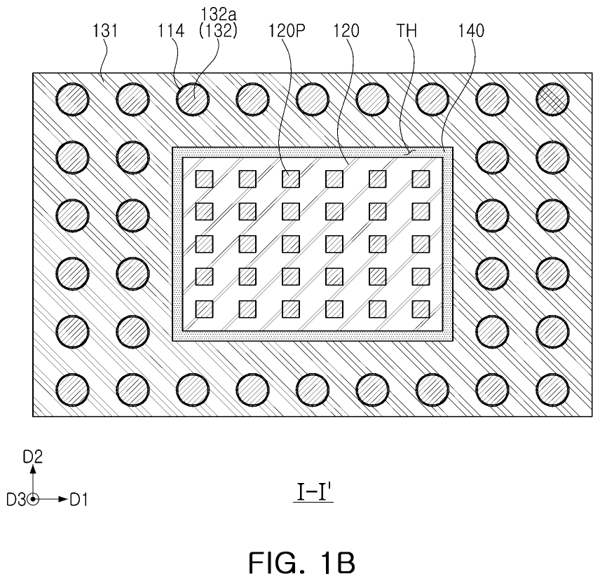

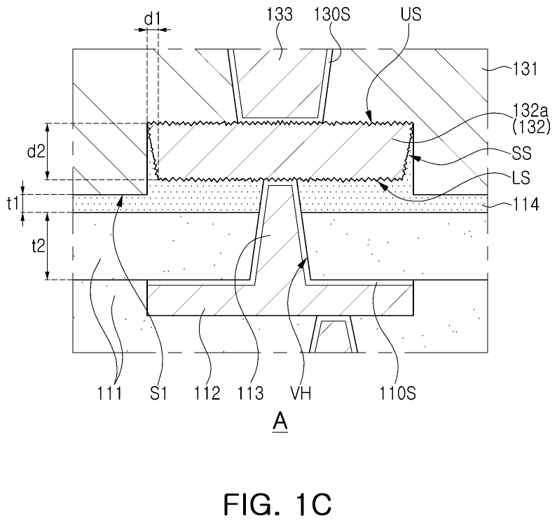

FIG. 1A is a cross-sectional view of a semiconductor package 100A according to at least one example embodiment, FIG. 1B is a plan view illustrating a cross-section taken along line I-I′ of FIG. 1A, and FIG. 1C is a partially enlarged view of portion ‘A’ of FIG. 1A.

Referring to FIGS. 1A to 1C, a semiconductor package 100A of the at least one example embodiment may include a first redistribution structure 110, a semiconductor chip 120, an interconnection structure 130, and a molded layer 140. Depending on an embodiment, the semiconductor package 100A may further include a second redistribution structure 150.

The first redistribution structure 110 may be disposed on the semiconductor chip 120 and the interconnection structure 130, and may include a first insulating layer 111, a first redistribution layer 112, a first redistribution via 113, and a gap fill layer 114. For example, the first redistribution structure 110 may be disposed below a first surface S1 of the interconnection structure 130 and an active surface 120S1 of the semiconductor chip 120.

The first insulating layer 111 may include an insulator, such as an insulating resin. The insulating resin may include, e.g., a thermosetting resin such as an epoxy resin, a thermoplastic resin such as polyimide, a resin containing an inorganic filler or/and a glass fiber (a glass fiber, a glass cloth, or a glass fabric), for example, a prepreg, an Ajinomoto build-up film (ABF), an FR-4, a bismaleimide-triazine (BT) based resin, and/or the like. For example, the first insulating layer 111 may include a photosensitive resin such as a photoimageable dielectric (PID). The first insulating layer 111 may include a plurality of first insulating layers stacked in a vertical direction D3. The first insulating layer 111 may include more or fewer layers than those illustrated in the drawings (e.g., three layers). Depending on a process forming the first insulating layer 111, a boundary between each of the plurality of layers in the first insulating layer 111 may be unclear.

The first redistribution layer 112 may be configured to redistribute the connection pads 120P of the semiconductor chip 120. The first redistribution layer 112 may include a conductive material, for example, a metal material including copper (Cu), aluminum (Al), silver (Ag), tin (Sn), gold (Au), nickel (Ni), lead (Pb), titanium (Ti), and/or alloys thereof. The first redistribution layer 112 may include a ground pattern, a power pattern, and a signal pattern. In at least one embodiment, the ground pattern and the power pattern may be, respectively, configured to provide a ground for and/or power to the semiconductor chip and/or the second redistribution structure 150; and the signal pattern may be configured to provide a path through which various signals (such as a data signal and/or the like) are transmitted/received and may therefore be distinguished from the ground pattern, the power pattern, and/or the like. The first redistribution layer 112 may include a plurality of first redistribution layers 112 respectively corresponding to a plurality of first insulating layers 111. The first redistribution layer 112 may include more or fewer layers than those illustrated in the drawings (e.g., three layers).

The first redistribution via 113 may be configured to electrically connect the first redistribution layer 112 to the connection pads 120P and interconnection patterns 132 and to connect different levels of the first redistribution layer 112. The first redistribution via 113 may include a conductive material, for example, a metal material including copper (Cu), aluminum (Al), silver (Ag), tin (Sn), gold (Au), nickel (Ni), lead (Pb), titanium (Ti), or alloys thereof. The first redistribution via 113 may form a filled via in which a metal material fills an internal space of a via hole and/or a conformal via in which a metal material is formed along an inner wall of the via hole. The first redistribution via 113 may be integrated with the first redistribution layer 112, but the present inventive concepts are not limited thereto.

In at least one example embodiment, the first redistribution via 113 may pass through the first insulating layer 111 between the first redistribution layer 112 and a first pattern layer 132a, and a gap fill layer 114. The first redistribution via 113 may be disposed in a via hole VH passing through both the gap fill layer 114 covering a lower surface LS of the first pattern layer 132a, and the first insulating layer 111 covering the gap fill layer 114. The first redistribution via 113 may be in contact with the lower surface LS of the first pattern layer 132a exposed through the via hole VH. A plating seed layer (or ‘seed layer’) 110S may be disposed between the first redistribution layer 112 and the first insulating layer 111, between the first redistribution via 113 and the first insulating layer 111, between the first redistribution via 113 and the gap fill layer between 114, and between the first redistribution via 113 and the first pattern layer 132a.

The gap fill layer 114 may be disposed between the interconnection structure 130 and the first redistribution structure 110. The gap fill layer 114 may cover at least a portion of a lowermost pattern layer 132a (hereinafter, “first pattern layer”) among the interconnection patterns 132. In some example embodiments, the gap fill layer 114 fills a gap between the first pattern layer 132a and an insulating material layer 131, thereby preventing (and/or reducing the propensity for) voids and cracks from occurring and improving reliability and yield of the semiconductor package. For example, the gap fill layer 114 may fill at least a portion of a first region between a side surface SS of the first pattern layer 132a and the insulating material layer 131, and at least a portion of a second region between the lower surface LS of the first pattern layer 132a and the first insulating layer 111. In a plan view (see FIG. 1B), the gap fill layer 114 may surround at least a portion of a circumference of the first pattern layer 132a.

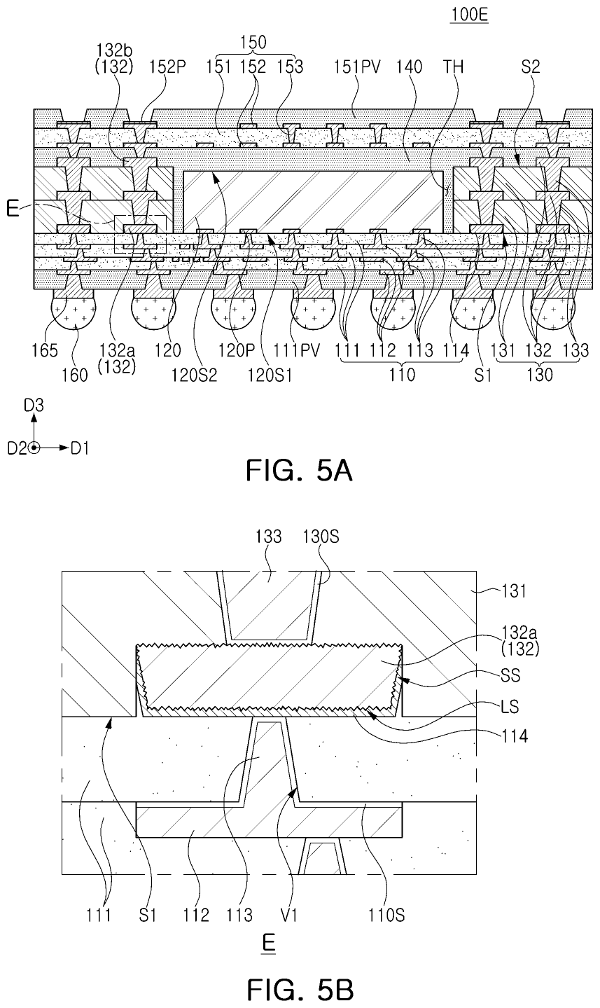

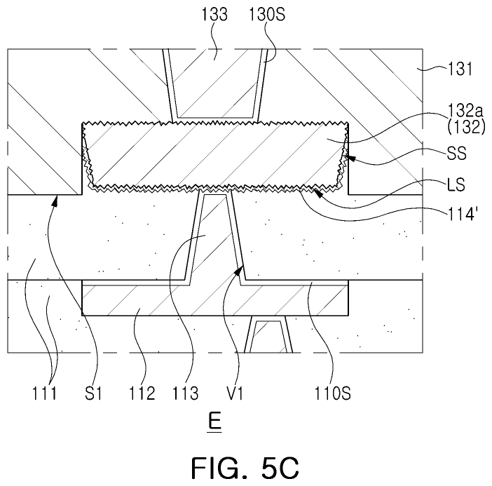

In at least one example embodiment, the gap fill layer 114 may be formed using an insulating resin having a lower viscosity than the first insulating layer 111, but the present inventive concepts are not limited thereto (embodiments of FIGS. 5A-5C). For example, the gap fill layer 114 may include a first insulating resin; and the first insulating layer 111 may include a second insulating resin. The viscosity of the first insulating resin (of the gap fill layer 114) may be lower than (or less than) a viscosity of the second insulating resin (of the first insulating layer 111). The viscosity of the first insulating resin forming the gap fill layer 114 may be about 50 centipoise (cP) or less, for example, about 0.2 cP to about 50 cP, about 5 cP to about 50 cP, about 10 cP to about 50 cP, about 15 cP to about 50 cP, about 20 cP to about 50 cP, and/or the like, but the present inventive concepts are not limited thereto.

In at least one example embodiment, both the gap fill layer 114 and the first insulating layer 111 may be formed using a photosensitive resin such as PID. The via hole VH in which the first redistribution via 113 is disposed may be formed through a photolithography process. The via hole VH may pass through both the gap fill layer 114 and the first insulating layer 111, and may have a shape tapered toward the first pattern layer 132a.

In at least one example embodiment, the gap fill layer 114 may extend in horizontal directions D1 and D2 below the first surface S1 of the interconnection structure 130 and the active surface 120S1 of the semiconductor chip 120. The gap fill layer 114 may cover at least a portion of each of the connection pads 120P of the semiconductor chip 120 and at least a portion of each of the first pattern layers 132a. A thickness t1 of the gap fill layer 114 covering the first surface S1 of the interconnection structure 130 may be smaller than a thickness t2 of the first insulating layer 111. The thickness t1 of the gap fill layer 114 may be defined as a distance from the first surface S1 of the interconnection structure 130 to a lower end of the gap fill layer 114. The thickness t2 of the first insulating layer 111 may be a thickness of an uppermost first insulating layer 111 contacting the gap fill layer 114, among the plurality of first insulating layers 111, for example, a distance from a lower end of the gap fill layer 114 to an uppermost first redistribution layer 112 (or seed layer 110S). The thickness t1 of the gap fill layer 114 may be about 15 micrometers (μm) or less, for example, about 0.01 μm to about 15 μm, about 1 μm to about 15 μm, about 5 μm to about 15 μm, about 10 μm to about 15 μm, but the present inventive concepts are not limited thereto. Connection bumps 160 may be disposed below the first redistribution structure 110.

The connection bumps 160 may connect the semiconductor package 100A to an external device such as a module substrate, a main board, and/or the like. The connection bumps 160 may include a low melting point metal, for example, tin (Sn), and/or an alloy containing tin (Sn) (for example, Sn—Ag—Cu).

Depending on the embodiment, the semiconductor package 100A may further include an underbump layer 165 and/or a first protective layer 111PV. The underbump layer 165 may be disposed between the first redistribution layer 112 and the connection bumps 160 and may be configured to electrically connect to each other, and thereby to provide an electrical path therebetween. The underbump layer 165 may have a thickness, greater than a thickness of the first redistribution layer 112. The underbump layer 165 may include a conductive material, for example, a metal material including copper (Cu), aluminum (Al), silver (Ag), tin (Sn), gold (Au), nickel (Ni), lead (Pb), titanium (Ti), and/or alloys thereof. The first protective layer 111PV may cover a lowermost first redistribution layer 112. The first protective layer 111PV may include an insulating resin such as an ABF. The underbump layer 165 may pass through the first protective layer 111PV, and may be connected to the first redistribution layer 112.

The semiconductor chip 120 may include connection pads 120P electrically connected to the first redistribution layer 112. The semiconductor chip 120 may have an active surface 120S1 on which the connection pads 120P are arranged, and an inactive surface 120S2 on a side opposite thereto. The semiconductor chip 120 may be disposed in the through-portion TH of the interconnection structure 130. The semiconductor chip 120 may be a bare integrated circuit (IC) without separate bumps or interconnection layers, but the present inventive concepts are not limited thereto, and may be a packaged-type integrated circuit. Therefore, a connection pad 120P can be understood as a pad of a bare chip (e.g., an aluminum (Al) pad) or a bump structure formed on the pad.

The semiconductor chip 120 may include various types of integrated circuits formed on an active wafer containing silicon (Si), germanium (Ge), or gallium arsenide (GaAs). The integrated circuits may be processor chips such as a central processor (CPU), a graphics processor (GPU), a field programmable gate array (FPGA), an application processor (AP), a digital signal processor, a cryptographic processor, a microprocessor, a microcontroller, or the like, but the present inventive concepts are not limited thereto, or may be logic chips such as an analog-to-digital converter, an application-specific IC (ASIC), and/or the like, and/or memory chips including a volatile memory (e.g., a DRAM, an SRAM), and/or a non-volatile memory (e.g., a PRAM, an MRAM, an FeRAM, an RRAM, or a flash memory).

The interconnection structure 130 may be disposed on the first redistribution structure 110. The interconnection structure 130 may occupy a space surrounding the semiconductor chip 120 to improve rigidity and bending of the semiconductor package 100A. Additionally, the interconnection structure 130 may be configured to provide an electrical path connecting the first redistribution layer 112 and a second redistribution layer 152 around the semiconductor chip 120. The interconnection structure 130 may include an insulating material layer 131, interconnection patterns 132, and interconnection vias 133.

The insulating material layer 131 may define a first surface S1, a second surface S2, opposite to each other, and the through-portion TH. The through-portion TH may extend from the first surface S1 to the second surface S2, and may provide a space for accommodating the semiconductor chip 120. The insulating material layer 131 may cover the interconnection patterns 132 and the interconnection vias 133, and may electrically insulate them. The insulating material layer 131 may include, for example, an insulating resin such as a prepreg, an ABF, an FR-4, a BT, and/or the like.

The interconnection patterns 132 and the interconnection vias 133 may be (and/or may include) a conductive material, such as copper (Cu), aluminum (Al), silver (Ag), tin (Sn), gold (Au), nickel (Ni), lead (Pb), titanium (Ti), and/or alloys thereof. In at least one embodiment, the interconnection patterns 132 and the interconnection vias 133 may be formed by a plating process such as a semi-additive process (SAP), a modified-SAP (MSAP), and/or the like. As such, a plating seed layer 130S may be disposed between the interconnection patterns 132 and the interconnection vias 133, and between the insulating material layer 131 and the interconnection vias 133. The interconnection patterns 132 and the interconnection vias 133 may include more or fewer layers than those illustrated in the drawings (e.g., three layers). The interconnection vias 133 may pass through the insulating material layer 131, and may electrically connect the interconnection patterns 132 to each other.

The interconnection patterns 132 may include first pattern layers 132a and second pattern layers 132b. Among the interconnection patterns 132, the first pattern layers 132a may be closest to the first surface S1, and may be connected to the first redistribution via 113. The first pattern layers 132a may be buried in one side of the insulating material layer 131, and may be located on a higher level than the first surface S1. Among the interconnection patterns 132, the second pattern layers 132b may be closest to the second surface S2, and may be connected to the second redistribution via 153. The second pattern layers 132b may protrude toward the other side of the insulating material layer 131, and may be located on a higher level than the second surface S2.

In at least one example embodiment, at least one first pattern layer 132a may be spaced apart from the insulating material layer 131 and the gap fill layer 114 may fill the gap therebetween. The gap fill layer 114 may prevent (and/or mitigate) voids and cracks from occurring by reducing a gap between the first pattern layer 132a and the insulating material layer 131. The gap between the first pattern layer 132a and the insulating material layer 131 may be caused by a difference in surface roughness of the first pattern layer 132a. For example, a side surface SS of the first pattern layer 132a may have a surface roughness, less than a surface roughness of a lower surface LS of the first pattern layer 132a. Depending on an embodiment, the side surface SS of the first pattern layer 132a may have a surface roughness, less than a surface roughness of an upper surface US of the first pattern layer 132a. For example, a surface roughness (Ra) of the lower surface LS of the first pattern layer 132a may be about 0.5 μm. In this case, “0.5 μm” may be only an example value for describing a state after surface treatment of the lower surface LS of the first pattern layer 132a, and does not limit conditions of a surface roughness treatment process. For example, the surface roughness (Ra) of the lower surface LS of the first pattern layer 132a may be 0.5 μm or more or 0.5 μm or less. This is only illustrative for cause of voids, and does not necessarily limit the fact that the gap between the first pattern layer 132a and the insulating material layer 131 may be caused by a difference in surface roughness. In example embodiments, the surface roughness of the side surface SS of the first pattern layer 132a may be substantially equal to the surface roughness of the lower surface LS of the first pattern layer 132a.

A gap or a region between the side surface SS of the first pattern layer 132a and the insulating material layer 131 may have, for example, a maximum width d1 of about 4 μm or more and a maximum depth d2 of about 10 μm or more. This merely illustrates a size of the gap in which voids and cracks are likely to occur, and a size of the gap to which a gap fill layer 114 of example embodiments is applied is not limited to the above-mentioned numerical range. The gap fill layer 114 may prevent (and/or mitigate) voids and cracks from occurring by filling at least a portion of the gap, thereby functionally reducing a width and a depth of the gap.

The molded layer 140 may cover at least a portion of the semiconductor chip 120 and at least a portion of the interconnection structure 130. The molded layer 140 may fill the through-portion TH of the interconnection structure 130, and may cover the second surface S2 of the interconnection structure 130. The molded layer 140 may include an insulating resin containing an inorganic filler, such as an ABF, an epoxy molding compound (EMC), and/or the like.

The second redistribution structure 150 may be opposite to the first redistribution structure 110. For example, the second redistribution structure 150 may be disposed on the second surface S2 of the interconnection structure 130 and the inactive surface 120S2 of the semiconductor chip 120. The second redistribution structure 150 may include a second insulating layer 151, a second redistribution layer 152, and a second redistribution via 153. Since the second insulating layer 151, the second redistribution layer 152, and the second redistribution via 153 may have the same or similar characteristics as the first insulating layer 111, the first redistribution layer 112, and the first redistribution via 113, described above, overlapping descriptions thereof will be omitted.

The second insulating layer 151 may include a different type of insulating resin than the molded layer 140. The second insulating layer 151 may include a material suitable for forming the second redistribution layer 152 and the second redistribution via 153 at a fine pitch, for example, a photosensitive resin such as PID.

The second redistribution via 153 may pass through the molded layer 140 to connect the second redistribution layer 152 to the second pattern layer 132b, or may pass through the second insulating layer 151 to interconnect second redistribution layers 152.

Depending on the embodiment, the second redistribution structure 150 may further include a surface finishing layer 152P and/or a second protective layer 151PV. The surface finishing layer 152P may be disposed on an uppermost second redistribution layer 152. The surface finishing layer 152P may include nickel (Ni) and/or gold (Au). The second protective layer 151PV may cover the uppermost second redistribution layer 152. The second protective layer 151PV may include an insulating resin such as an ABF. The second protective layer 151PV may have openings exposing at least a portion of the surface finishing layer 152P.

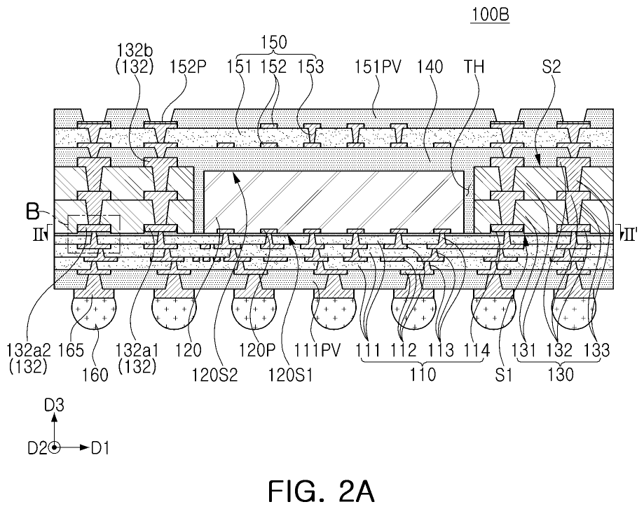

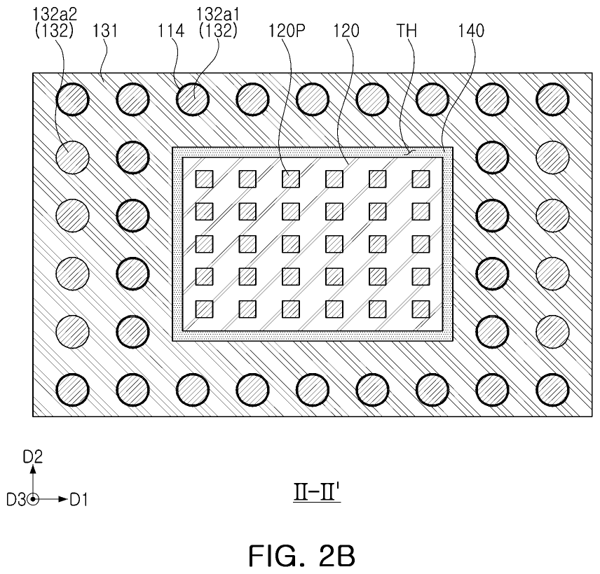

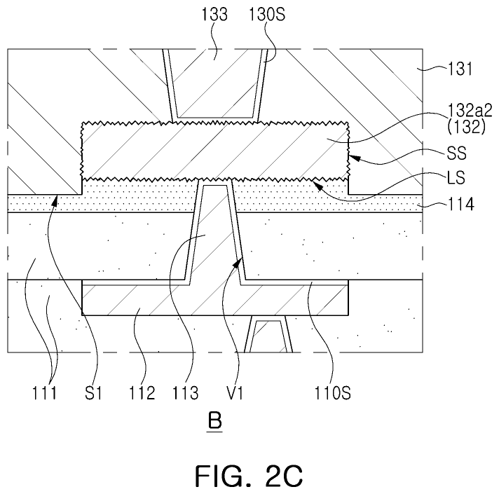

FIG. 2A is a cross-sectional view of a semiconductor package 100B according to at least one example embodiment, FIG. 2B is a plan view illustrating a cross-section taken along line II-II′ of FIG. 2A, and FIG. 2C is a partially enlarged view of portion ‘B’ of FIG. 2A.

Referring to FIGS. 2A to 2C, a semiconductor package 100B of the at least one example embodiment may have the same and/or similar features as those described with reference to FIGS. 1A to 1C, except that first pattern layers 132a2 laterally contacting an insulating material layer 131 are included. An interconnection structure 130 may include a first group of first pattern layers 132a1 and a second group of first pattern layers 132a2.

As described with reference to FIGS. 1A to 1C, the first group of first pattern layers 132a1 may have a gap between them and the insulating material layer 131, and at least a portion of the gap may be filled by a gap fill layer 114 (see FIG. 1C). Depending on the embodiment, the first group of first pattern layers 132a1 may include only one first pattern layer 132a1. Depending on the embodiment, the first group of first pattern layers 132a1 may include a plurality of the first pattern layers 132a1.

The second group of first pattern layers 132a2 can be understood as having a side surface SS in close contact with the insulating material layer 131 and/or having a fine gap such that the gap fill layer 114 does not penetrate (FIG. 2C).

The gap fill layer 114 may fill the gap between the first group of the first pattern layers 132al and the insulating material layer 131, thereby preventing (and/or mitigating) voids and cracks from occurring and improving reliability and yield of the semiconductor package without requiring the reprocessing of the first pattern layers 132a1.

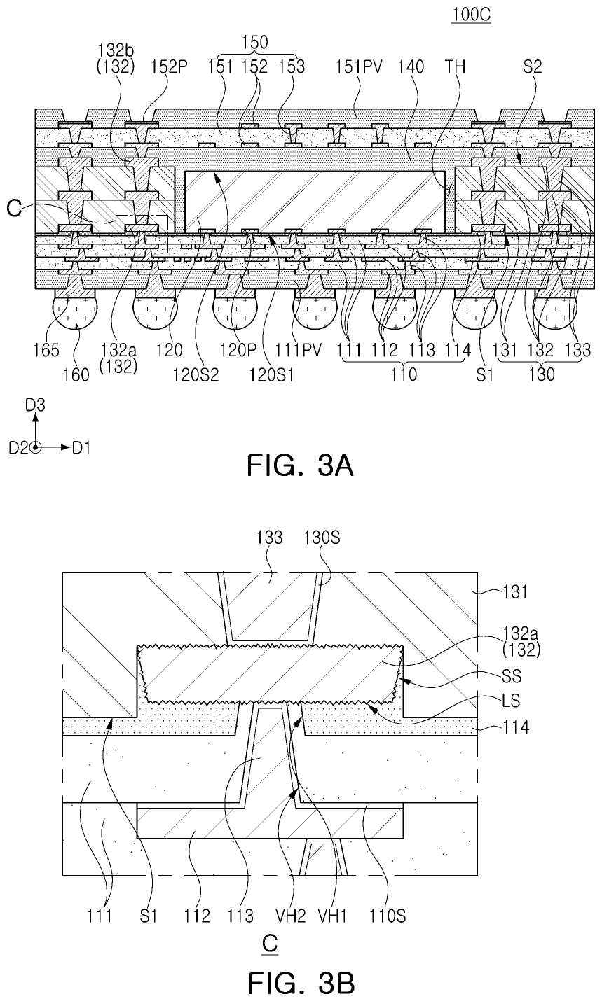

FIG. 3A is a cross-sectional view of a semiconductor package 100C according to at least one example embodiment, and FIG. 3B is a partial enlarged view of portion ‘C’ of FIG. 3A.

Referring to FIGS. 3A and 3B, a semiconductor package 100C of the at least one example embodiment may have the same or similar features as those described with reference to FIGS. 1A to 2C, except that a first redistribution via 113 passes through a first via hole VH1 and a second via hole VH2. A gap fill layer 114 may have the first via hole VH1 exposing at least a portion of a lower surface LS of a first pattern layer 132a, and a first insulating layer 111 may have the second via hole VH2 passing through the first via hole VH1.

A width of the first via hole VH1 may be larger than a width of the second via hole VH2. The first via hole VH1 and the second via hole VH2 may be formed by different processes. The first via hole VH1 and the second via hole VH2 may be tapered in the same direction. In the present embodiment, the gap fill layer 114 may include a non-photosensitive resin, and the first insulating layer 111 may include a photosensitive resin, but the present inventive concepts are not limited thereto. The gap fill layer 114 may include a photosensitive resin or a non-photosensitive resin having flowability and/or viscosity capable of filling a gap between the first pattern layer 132a and an insulating material layer 131.

The first redistribution via 113 may be disposed in the second via hole VH2. The first redistribution via 113 may be in contact with the lower surface LS of the first pattern layer 132a exposed through the second via hole VH2.

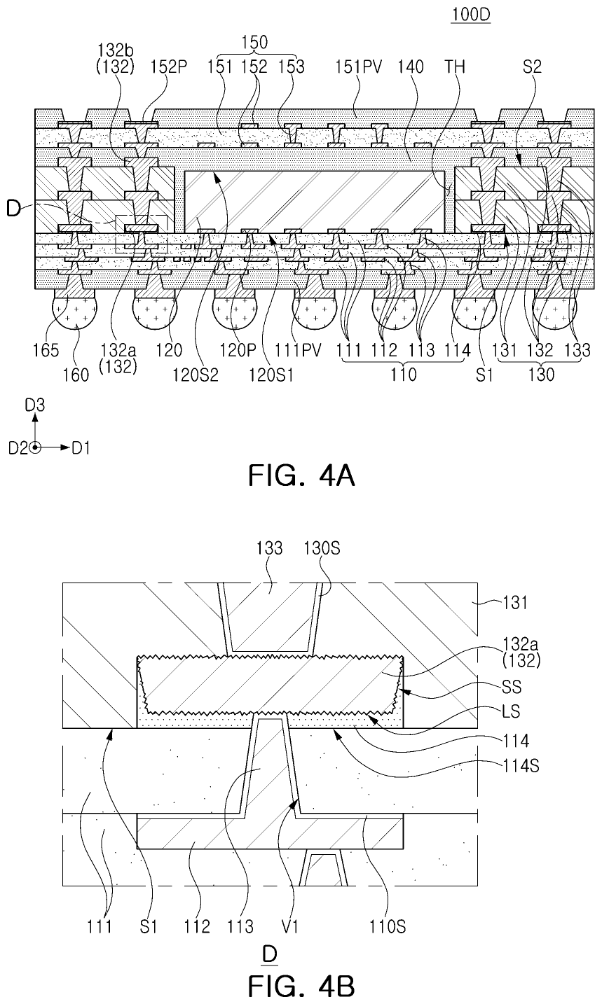

FIG. 4A is a cross-sectional view of a semiconductor package 100D according to at least one example embodiment, and FIG. 4B is a partial enlarged view of portion ‘D’ of FIG. 4A.

Referring to FIGS. 4A and 4B, a semiconductor package 100D of the at least one example embodiment may have the same or similar features as those described with reference to FIGS. 1A to 3B, except that a gap fill layer 114 does not cover a first surface S1 of an interconnection structure 130. A lower surface 114S of the gap fill layer 114 may be on a level, equal to or higher than the first surface S1 of the interconnection structure 130. The lower surface 114S of the gap fill layer 114 may be located on a level between a lower surface LS of a first pattern layer 132a and the first surface S1 of the interconnection structure 130. The gap fill layer 114 of the present embodiment may be formed by partially applying an insulating resin only on the first pattern layer 132a, on the first surface S1 of the interconnection structure 130, and/or by applying a surface cutting process to an insulating resin applied entirely on the first surface S1 of the interconnection structure 130, but the present inventive concepts are not limited thereto.

FIG. 5A is a cross-sectional view of a semiconductor package 100E according to at least one example embodiment, FIG. 5B is a partial enlarged view of portion ‘E’ of FIG. 5A, and FIG. 5C is a view illustrating an example modification of portion ‘E’.

Referring to FIGS. 5A to 5C, a semiconductor package 100E of the at least one example embodiment may have the same or similar features as those described with reference to FIGS. 1A to 4B, except that a gap fill layer 114 includes a conductive material. The gap fill layer 114 may include, for example, a metal material including copper (Cu), aluminum (Al), silver (Ag), tin (Sn), gold (Au), nickel (Ni), lead (Pb), titanium (Ti), or alloys thereof. The gap fill layer 114 may be formed by a deposition process, a plating process, or the like. For example, the gap fill layer 114 may be formed by a sputtering process. A first redistribution via 113 may be in contact with the gap fill layer 114 covering a lower surface LS of a first pattern layer 132a. As illustrated in FIG. 5B, the gap fill layer 114 may extend along a side surface SS and the lower surface LS of the first pattern layer 132a, and may partially fill a region between the side surface SS of the first pattern layer 132a and an insulating material layer 131. As illustrated in FIG. 5C, a gap fill layer 114′ of an example modification may have a surface roughness appearing in surface irregularities on a side surface SS and a lower surface LS of a first pattern layer 132a.

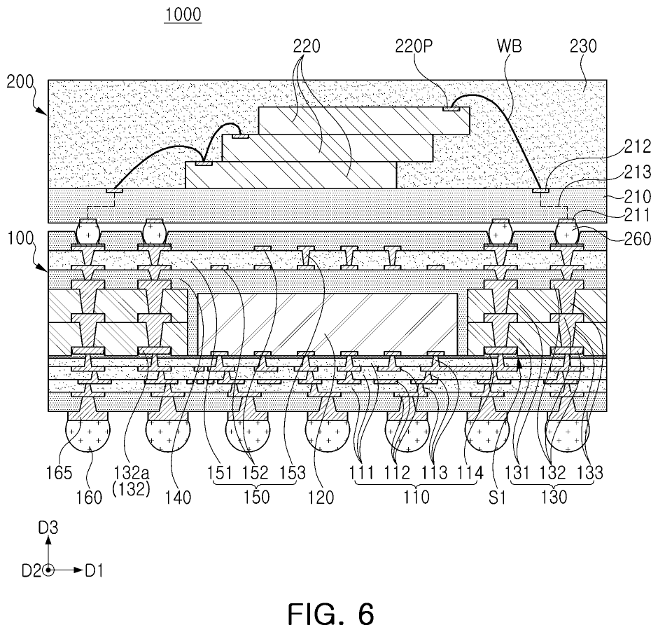

FIG. 6 is a cross-sectional view of a semiconductor package 1000 according to at least one example embodiment.

Referring to FIG. 6, a semiconductor package 1000 of the at least one example embodiment may have a package-on-package structure including a first package 100 and a second package 200. The first package 100 may have the same or similar characteristics as the semiconductor packages 100A, 100B, 100C, 100D, and 100E described with reference to FIGS. 1A to 5C.

The second package 200 may include a substrate 210, a second semiconductor chip 220, and an encapsulant 230. The substrate 210 may include a lower pad 211 and an upper pad 212. The substrate 210 may include a redistribution circuit 213 connected to the lower pad 211 and the upper pad 212.

The second semiconductor chip 220 may be mounted on the substrate 210 using a wire bonding process, a flip chip bonding process, and/or the like. For example, a plurality of second semiconductor chips 220 may be stacked on the substrate 210 in a vertical direction, and may be electrically connected to the upper pad 212 of the substrate 210 through a bonding wire WB. In an example, the second semiconductor chip 220 may include a memory chip, and a first semiconductor chip 120 may include an AP chip.

The encapsulant 230 may include the same or similar material as a molded layer 140 of the first package 100. The second package 200 may be physically and electrically connected to the first package 100 by a conductive bump 260. The conductive bump 260 may be electrically connected to the redistribution circuit 213 of the substrate 210 through the lower pad 211. The conductive bump 260 may be formed of a low melting point metal, for example, tin (Sn) or an alloy containing tin (Sn).

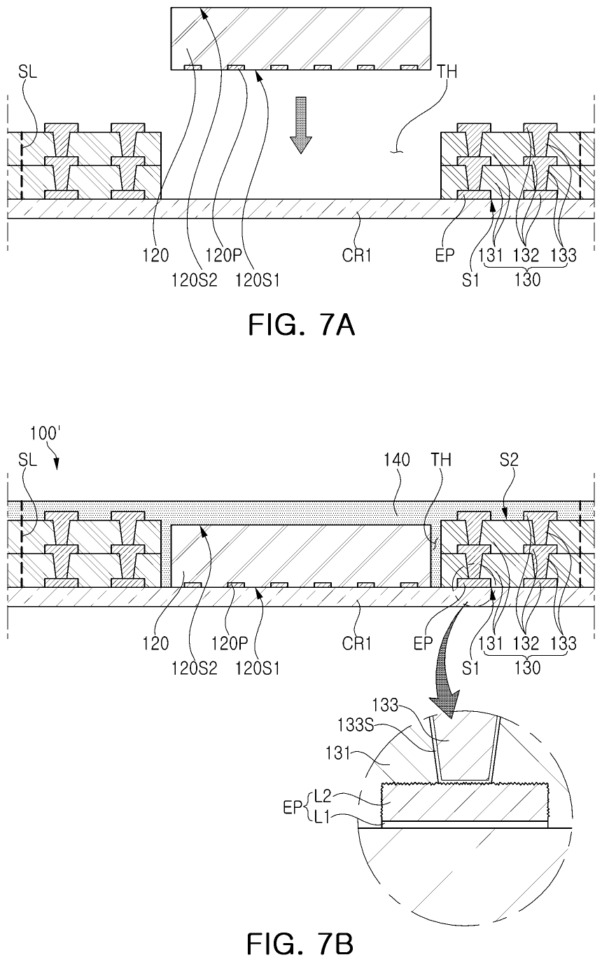

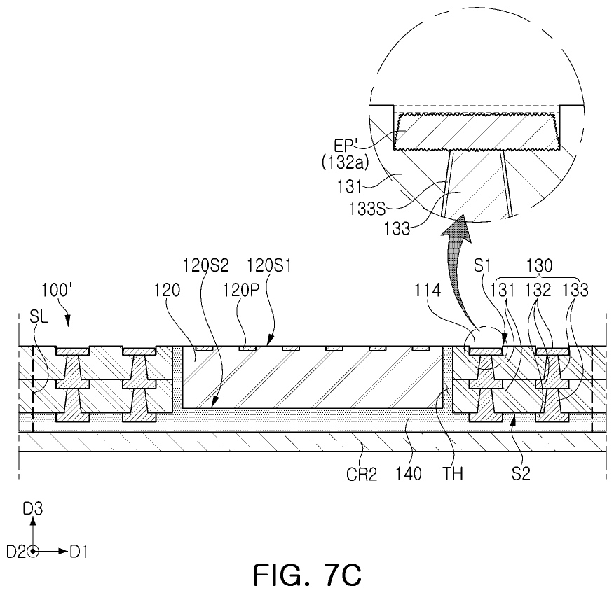

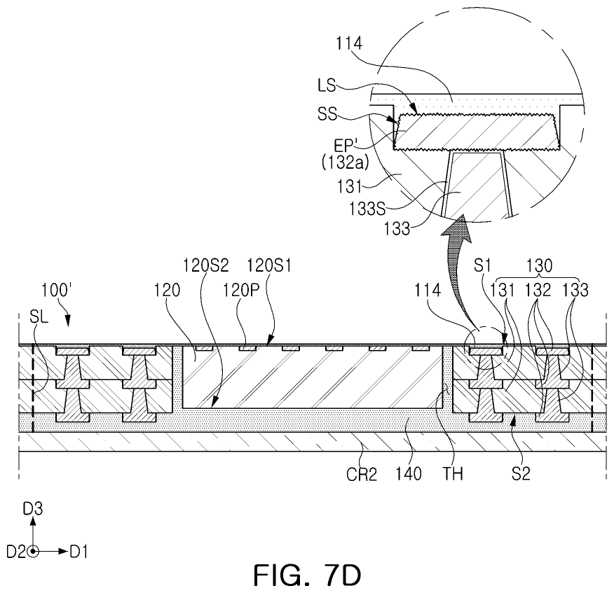

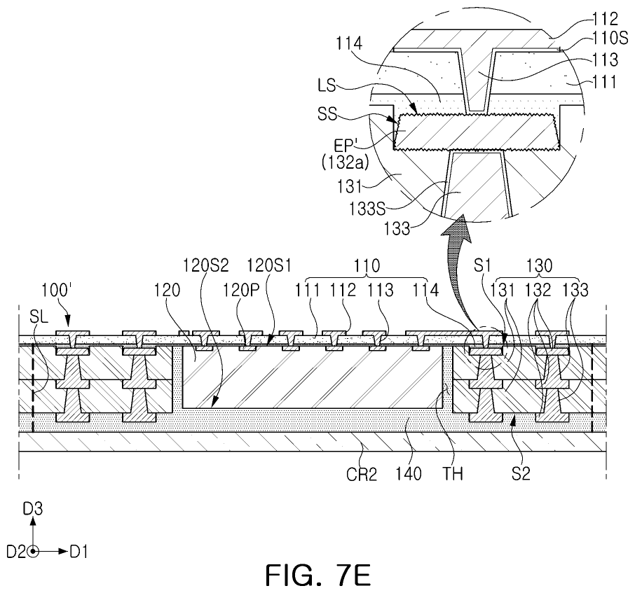

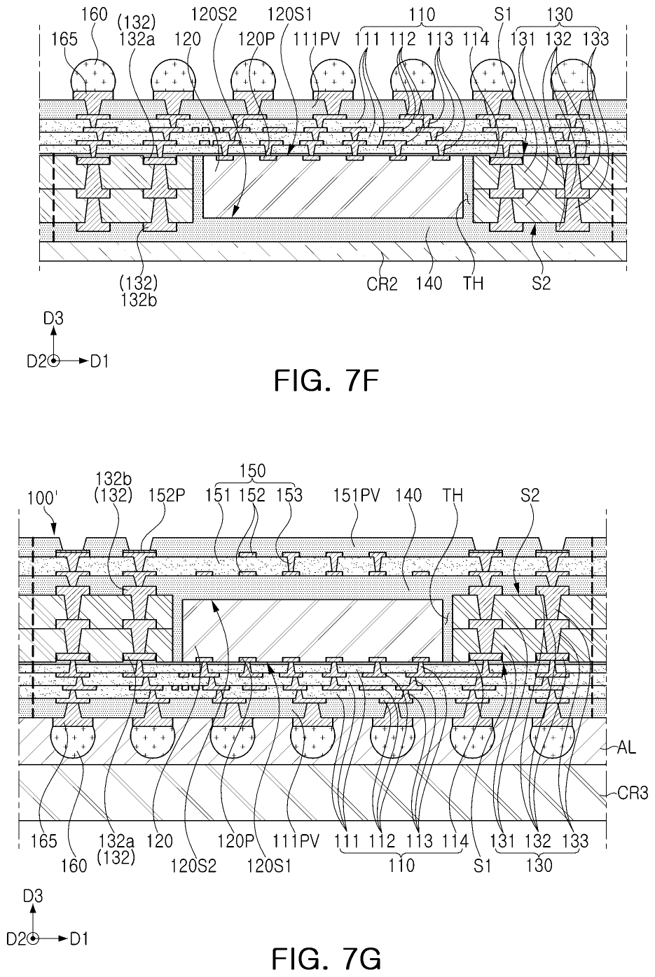

FIGS. 7A to 7G are views illustrating a process of manufacturing the semiconductor package illustrated in FIG. 1A.

Referring to FIG. 7A, an interconnection structure 130 and a semiconductor chip 120 may be attached to a first carrier CR1. The first carrier CR1 may include an adhesive tape selected to temporarily support and fix the interconnection structure 130 and the semiconductor chip 120.

The interconnection structure 130 may include an insulating material layer 131, interconnection patterns 132, and interconnection vias 133. The interconnection structure 130 may include a plurality of unit substrates separated by a scribe line SL. Additionally, the interconnection patterns 132 may include embedded pattern layers EP buried in the insulating material layer 131 to expose a lower surface thereof.

The semiconductor chip 120 may be disposed in a through-portion TH of the interconnection structure 130. The semiconductor chip 120 may be disposed such that an active surface 120S1 on which connection pads 120P are disposed faces the first carrier CR.

Referring to FIG. 7B, a molded layer 140 may be formed on the first carrier CR1. The molded layer 140 may cover at least a portion of the interconnection structure 130 and at least a portion of the semiconductor chip 120. For example, the molded layer 140 may be formed by transferring a film-type insulating resin such as ABF. A planarization process (e.g., grinding process) may be applied to an upper portion of the molded layer 140. Lower surfaces of the embedded pattern layers EP may not be covered by the molded layer 140. The embedded pattern layers EP may include a first metal layer L1 and a second metal layer L2. The first metal layer L1 may be a plating seed layer provided for plating the second metal layer L2. The first metal layer L1 and the second metal layer L2 may include, for example, copper (Cu) and/or an alloy thereof. The embedded pattern layers EP may be in a state in which a surface of thereof is roughened (e.g., after a copper-selective processes such as CZ treated in the case wherein the second metal layer L2 includes copper). The semiconductor chip 120 and the interconnection structure 130, integrated by the molded layer 140, may hereinafter be referred to as a preliminary package structure 100′.

Referring to FIG. 7C, the preliminary package structure 100′ may be attached to a second carrier CR2. The preliminary package structure 100′ may be disposed such that the connection pads 120P of the semiconductor chip 120 and the embedded pattern layers EP of the interconnection structure 130 exposed after removing the first carrier CR1 are exposed.

Thereafter, an etching process and a surface treatment process may be applied to the embedded pattern layers EP. The first metal layer L1 may be removed by the etching process. Roughness may be formed on a surface of the second metal layer L2 exposed from the insulating material layer 131 by the surface treatment process. During the etching process and the surface treatment process, the connection pads 120P may be masked using a dry film and/or the like.

Roughness-treated embedded pattern layers EP' can be understood as elements corresponding to a first pattern layer 132a, as described above. A gap having a depth and width may be formed between a side surface of the roughness-treated embedded pattern layers EP′ and the insulating material layer 131. This may be caused by the etching process and surface treatment process, described above, but may also be caused by a decrease in adhesion between the side surfaces of the embedded pattern layers EP′, which have a relatively small surface roughness, and the insulating material layer 131. The gap between the side surface of the embedded pattern layers EP′ and the insulating material layer 131 may be caused by various causes. To emphasize the gap between the insulating material layer 131 and the roughness-treated embedded pattern layers EP′, the roughened embedded pattern layers EP' are illustrated in a trapezoidal shape, but is illustrative and is not limited thereto.

Referring to FIG. 7D, a gap fill layer 114 may be formed on the preliminary package structure 100′. The gap fill layer 114 may be formed entirely on an upper surface of the preliminary package structure 100′. The gap fill layer 114 may fill a gap between a side surface SS of the embedded pattern layers EP' and the insulating material layer 131. The gap fill layer 114 may be formed by applying and/or curing a photosensitive resin having a viscosity of about 50 cP or less, for example, PID. The gap fill layer 114 may be formed to have a thickness of about 15 μm or less. The gap fill layer 114 may prevent voids and cracks from occurring between the embedded pattern layers EP′ and the insulating material layer 131, to improve yield and reliability of subsequent processes.

Referring to FIG. 7E, a first insulating layer 111 may be formed on the gap fill layer 114. The first insulating layer 111 may be formed by applying and/or curing a photosensitive resin having a viscosity of about 50 cP or more, for example, PID. For example, the first insulating layer 111 may be formed using a photosensitive resin having a viscosity ranging from about 55 cP to about 60 cP. A via hole passing through the gap fill layer 114 and the first insulating layer 111 may be formed by performing an exposure process and a development process (e.g., using a photomask). Next, a first redistribution layer 112 and a first redistribution via 113 may be formed using a deposition process, a plating process, an etching process, and/or the like. The first redistribution via 113 may pass through the gap fill layer 114 and the first insulating layer 111, and may be in contact with an upper surface LS of the embedded pattern layers EP′.

Referring to FIG. 7F, a first redistribution structure 110, a first protective layer 111PV, an underbump layer 165, and connection bumps 160 may be formed on the preliminary package structure 100′. The first redistribution structure 110 may be formed by repeatedly performing the process described with reference to FIG. 7E. The first protective layer 111PV may be formed using, for example, ABF. The underbump layer 165 may be formed using a plating process. The connection bumps 160 may be formed by attaching a flux, a solder ball, and the like to the underbump layer 165, and then using a reflow process.

Referring to FIG. 7G, unit packages 100U may be manufactured by forming a second redistribution structure 150, a second protective layer 151PV, and a surface finishing layer 152P. The unit packages 100U may be attached to a third carrier CR3 such that the connection bumps 160 are embedded in an adhesive layer AL.

The second redistribution structure 150 may include a second insulating layer 151, second redistribution layers 152, and second redistribution vias 153. The second insulating layer 151, the second redistribution layer 152, and the second redistribution via 153 may be formed in a similar manner to the first insulating layer 111, the first redistribution layer 112, and the first redistribution via 113, described with reference to FIGS. 7E and 7F. Thereafter, the unit packages 100U may be separated from each other along the scribe line SL.

According to some embodiments, a semiconductor package having improved reliability and a method of manufacturing the same may be provided by introducing a gap fill layer that fills the space between the side surface of the pattern layer and the insulating material layer.

Various advantages and effects of the present inventive concepts are not limited to the above-described content, and can be more easily understood through description of specific embodiments.

While some example embodiments have been illustrated and described above, it will be apparent to those skilled in the art that modifications and variations could be made without departing from the scope of the present inventive concepts as defined by the appended claims.

1. A semiconductor package comprising:
an interconnection structure including
interconnection patterns,
an insulating material layer covering at least a portion of the interconnection patterns, the insulating material layer defining opposing first and second surfaces and a through-portion extending from the first surface to the second surface, and
interconnection vias electrically connecting the interconnection patterns in the insulating material layer;
a semiconductor chip in the through-portion, the semiconductor chip including connection pads;
a molded layer covering at least a portion of the semiconductor chip and at least a portion of the interconnection structure;
a first redistribution structure below the first surface of the interconnection structure and including
a gap fill layer covering at least a portion of the interconnection patterns,
a first insulating layer covering the gap fill layer,
a first redistribution layer below the first insulating layer, and
a first redistribution via electrically connecting the first redistribution layer to the connection pads and the interconnection patterns;
a second redistribution structure on the second surface of the interconnection structure, the second redistribution structure including
a second redistribution layer on the molded layer, and
a second redistribution via electrically connecting the second redistribution layer to the interconnection patterns; and
connection bumps below the first redistribution structure and electrically connected to the first redistribution layer,
wherein the interconnection patterns include a first pattern layer adjacent to the first surface and embedded in the insulating material layer, and a second pattern layer adjacent to the second surface and protruding from the insulating material layer, and
wherein the gap fill layer fills at least a portion of a first region between a side surface of the first pattern layer and the insulating material layer, and at least a portion of a second region between a lower surface of the first pattern layer and the first insulating layer.

2. The semiconductor package of claim 1, wherein the gap fill layer comprises a first insulating resin,
the first insulating layer comprises a second insulating resin,
wherein a viscosity of the first insulating resin is less than a viscosity of the second insulating resin.

3. The semiconductor package of claim 2, wherein the viscosity of the first insulating resin is about 50 centipoise (cP) or less.

4. The semiconductor package of claim 2, wherein the first insulating resin and the second insulating resin each comprise a photosensitive resin.

5. The semiconductor package of claim 1, wherein the first redistribution via is in a via hole passing through the first insulating layer and the gap fill layer such that
the first redistribution via is in contact with the lower surface of the first pattern layer exposed through the via hole.

6. The semiconductor package of claim 5, wherein the first redistribution structure further comprises a seed layer between the first redistribution layer and the first insulating layer, between the first redistribution via and the first insulating layer, between the first redistribution via and the gap fill layer, and between the first redistribution via and the first pattern layer.

7. The semiconductor package of claim 1, wherein the gap fill layer has a first via hole exposing at least a portion of the lower surface of the first pattern layer,
the first insulating layer has a second via hole passing through the first via hole,
the first redistribution via is in the second via hole, and
the first redistribution via is in electrical contact with the lower surface of the first pattern layer through the second via hole.

8. The semiconductor package of claim 1, wherein the gap fill layer extends in a horizontal direction such that the gap fill layer covers at least a portion of each of the connection pads of the semiconductor chip.

9. The semiconductor package of claim 8, wherein a thickness of the gap fill layer is smaller than a thickness of the first insulating layer.

10. The semiconductor package of claim 9, wherein the thickness of the gap fill layer is about 15 micrometer (μm) or less.

11. The semiconductor package of claim 1, wherein the gap fill layer comprises a conductive material and extends along the side surface and the lower surface of the first pattern layer.

12. The semiconductor package of claim 11, wherein the first redistribution via is in electrical contact with the gap fill layer covering the lower surface of the first pattern layer and the first pattern layer.

13. The semiconductor package of claim 1, wherein the side surface of the first pattern layer has a surface roughness less than or equal to a surface roughness of the lower surface of the first pattern layer.

14. The semiconductor package of claim 1, wherein a maximum width of the first region is about 4 micrometer (μm) or more, and
a maximum depth of the first region is about 10 μm or more.

15. A semiconductor package comprising:
an interconnection structure including
an insulating material layer defining opposing first and second surfaces and a through-portion extending from the first surface to the second surface,
first pattern layers adjacent to the first surface and embedded in the insulating material layer, and
second pattern layers adjacent to the second surface and protruding on the insulating material layer;
a semiconductor chip in the through-portion of the interconnection structure, the semiconductor chip including connection pads on an active surface;
a molded layer covering at least a portion of the semiconductor chip and at least a portion of the interconnection structure; and
a redistribution structure below the first surface of the interconnection structure and the active surface of the semiconductor chip, the redistribution structure including
a gap fill layer covering at least a portion of each of the first pattern layers,
an insulating layer covering the gap fill layer,
a redistribution layer below the insulating layer, and
a redistribution via electrically connecting the redistribution layer to the connection pads and the first pattern layers,
wherein at least a portion of the gap fill layer is between the insulating material layer and a side surface of at least one first pattern layer among the first pattern layers.

16. The semiconductor package of claim 15, wherein a surface roughness of the side surface of the at least one first pattern layer is less than a surface roughness of upper and lower surfaces of the at least one first pattern layer.

17-20. (canceled)
